(19) United States
(12) Patent Application Publication
(10) Pub. No.: US 2025/0308896 A1
(43) Pub. Date: Oct. 2, 2025

(54) MULTIPLE PATTERNING UTILIZING A TWO-COLOR SPACER DESIGN

(71) Applicant: Tokyo Electron Limited, Tokyo (JP)

(72) Inventors: Katie LUTKER-LEE, Albany, NY (US); Eric Chih-Fang LIU, Albany, NY (US)

(73) Assignee: Tokyo Electron Limited, Tokyo (JP)

(21) Appl. No.: 18/620,366

(22) Filed: Mar. 28, 2024

(51) Int. Cl. H01L 21/033; H01L 21/308

(52) U.S. Cl. CPC H01L 21/0337; H01L 21/3086

(57) ABSTRACT

A method of microfabrication is provided. The method includes providing a wafer having a patterned layer formed thereon. The patterned layer includes a mandrel structure having a first sidewall and a second sidewall on opposing sides of the mandrel structure. A first spacer is formed on the first sidewall of the mandrel structure by asymmetric deposition, asymmetric etch or a combination thereof. A second spacer is formed on the second sidewall of the mandrel structure so that the first spacer, the mandrel structure and the second spacer form a three-material structure. A first etch mask is formed over the patterned layer. The first etch mask includes a first opening that exposes the three-material structure. One or two materials of the three-material structure are selectively removed via the first opening.

### FIELD OF THE INVENTION

This disclosure relates generally to methods of microfabrication and more specifically to lithography and patterning.

### BACKGROUND

In the manufacture of a semiconductor device (especially on the microscopic scale), various fabrication processes are executed such as film-forming depositions, etch mask creation, material etching and removal, doping treatments and the like. These processes are performed repeatedly to form desired semiconductor device elements on a substrate. As device dimensions continue to shrink, multiple patterning (or multi-patterning) has gained much attention in recent years. When a single lithographic exposure is not enough to provide sufficient resolution, one or more additional exposures might be needed, or else positioning patterns using etched feature sidewalls (using spacers) could be necessary.

### SUMMARY

According to some aspects of the present disclosure, a method of microfabrication is provided. The method includes providing a wafer having a patterned layer formed thereon. The patterned layer includes a mandrel structure having a first sidewall and a second sidewall on opposing sides of the mandrel structure. A first spacer is formed on the first sidewall of the mandrel structure by asymmetric deposition, asymmetric etch or a combination thereof. A second spacer is formed on the second sidewall of the mandrel structure so that the first spacer, the mandrel structure and the second spacer form a three-material structure. A first etch mask is formed over the patterned layer. The first etch mask includes a first opening that exposes the three-material structure. One or two materials of the three-material structure are selectively removed via the first opening.

In some embodiments, the first opening of the first etch mask is not aligned with the three-material structure in that at least one boundary of the first etch mask is outside the three-material structure.

In some embodiments, the wafer includes a top layer that is in direct contact with the patterned layer, and the first opening of the first etch mask also exposes the top layer of the wafer.

In some embodiments, the first opening exposes four different materials consisting of the first spacer, the mandrel structure, the second spacer and the top layer.

In some embodiments, the selectively removing includes selectively etching the first spacer, or both the first spacer and the mandrel structure, in the first opening.

In some embodiments, the first etch mask is removed. A second etch mask is formed over the patterned layer. The second etch mask includes a second opening that exposes the three-material structure. The second spacer, or both the second spacer and the mandrel structure, are selectively etched in the second opening.

In some embodiments, the selectively removing includes selectively etching the second spacer, or both the second spacer and the mandrel structure, in the first opening.

In some embodiments, the first etch mask is removed. A second etch mask is formed over the patterned layer. The second etch mask includes a second opening that exposes the three-material structure. The first spacer, or both the first spacer and the mandrel structure, are selectively etched in the second opening.

In some embodiments, a gap is formed in the mandrel structure to divide the mandrel structure into two sub-mandrel structures that are spaced apart from each other by the gap. The gap is filled with the first spacer.

In some embodiments, a first spacer material is formed isotropically around the mandrel structure, including in the gap. A directional etch process is executed that has an acute angle relative to a working surface of the wafer so that remaining portions of the first spacer material forms the first spacer that is on the first sidewall of the mandrel structure and fills the gap.

In some embodiments, the first spacer is formed on the first sidewall of the mandrel structure at least by the asymmetric deposition that includes forming a first spacer material on the first sidewall of the mandrel structure and on a top surface of the mandrel structure by a directional plasma that has an acute angle relative to a working surface of the wafer. The first spacer material is removed from the top surface of the mandrel structure by an anisotropic etch process so that remaining portions of the first spacer material forms the first spacer.

In some embodiments, the acute angle is 30°-85°.

In some embodiments, the first spacer is formed on the first sidewall of the mandrel structure at least by the asymmetric etch that includes forming a first spacer material on the first sidewall of the mandrel structure and on the second sidewall of the mandrel structure. The first spacer material is removed from the second sidewall of the mandrel structure by a directional etch process that has an acute angle relative to a working surface of the wafer.

In some embodiments, an anisotropic etch process is executed that is substantially perpendicular to the working surface of the wafer to etch the first spacer material.

In some embodiments, the first spacer, the mandrel structure and the second spacer are configured to be etch-selective to each other.

In some embodiments, the mandrel structure includes silicon nitride, spin-on carbon, amorphous carbon, amorphous silicon, or a combination thereof. The first spacer includes silicon oxide, silicon nitride, titanium oxide, titanium nitride, or a combination thereof. The second spacer includes silicon oxide, silicon nitride, titanium oxide, titanium nitride, or a combination thereof.

In some embodiments, the mandrel structure includes silicon nitride. One of the first spacer and the second spacer includes silicon oxide. The other one of the first spacer and the second spacer includes titanium oxide, titanium nitride, or a combination thereof.

In some embodiments, the mandrel structure includes amorphous silicon. One of the first spacer and the second spacer includes titanium oxide. The other one of the first spacer and the second spacer includes silicon oxide.

In some embodiments, the wafer includes a top layer that is in direct contact with the patterned layer. The top layer includes silicon, germanium, silicon germanium, or a combination thereof.

In some embodiments, the patterned layer includes a plurality of mandrel structures that extend substantially parallel to one another.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a flow chart of a process of patterning, in accordance with some embodiments of the present disclosure.

FIG. 2 shows a vertical cross-sectional view of a semiconductor device in accordance with some embodiments of the present disclosure.

FIGS. 3A, 4A, 5A and 6A show top-down views of a semiconductor device at various intermediate steps of patterning, in accordance with some embodiments of the present disclosure.

FIG. 3B shows a vertical cross-sectional view taken along the line cut AA′ in FIG. 3A in accordance with one embodiment of the present disclosure.

FIG. 4B shows a vertical cross-sectional view taken along the line cut BB′ in FIG. 4A in accordance with one embodiment of the present disclosure.

FIG. 5B shows a vertical cross-sectional view taken along the line cut CC′ in FIG. 5A in accordance with one embodiment of the present disclosure.

FIG. 6B shows a vertical cross-sectional view taken along the line cut DD′ in FIG. 6A in accordance with one embodiment of the present disclosure.

FIGS. 7A, 7B, 7C and 7D show top-down views of a semiconductor device at various intermediate steps of patterning, in accordance with some embodiments of the present disclosure.

FIGS. 8A, 8B, 8C and 8D show top-down views of a semiconductor device at various intermediate steps of patterning, in accordance with some embodiments of the present disclosure.

FIGS. 9A, 9B and 9C show top-down views of a semiconductor device at various intermediate steps of patterning, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the background, the need to pattern smaller and smaller features for semiconductor devices is ever growing. Methods to scale beyond the current lithography limit are thus necessary and yet elusive. For example in self-aligned multiple patterning (SAMP), conventional methods rely on selectivity to various films in order to achieve alignment of cuts and blocks for the metal lines. State-of-the-art self-aligned block (SAB) patterning utilizes three colors (or three different materials) including a mandrel, a single-color spacer and an underlying layer. However, it can only cut or block the mandrel and non-mandrel areas but not the spacer.

Techniques herein use asymmetric deposition, asymmetric etch, or a combination of asymmetric deposition and asymmetric etch. As a result, an additional color (or material) can be introduced into a line/space starting grid that will allow for more selective cuts to be placed in the spacer side without worrying as much about lithographic overlay issues, such as edge placement errors (EPE). That is to say, compared with traditional SAB patterning that utilizes three colors, a four-color grid can be achieved herein, which will allow for novel cut and block patterning schemes to be used without overlayer issues.

The present disclosure provides a method to utilize asymmetric deposition and etch for advanced pattern formation. The method herein allows for an expansion of multi-color and complex cut design capabilities as well as enables the spacer cut capability (conventionally only able to cut in the mandrel and non-mandrel areas). The method herein can utilize selective etch/deposition and/or partially selective etch/deposition for pattern formation. The method herein can also incorporate non-mandrel side cuts/block integration to provide even more pattern complexity.

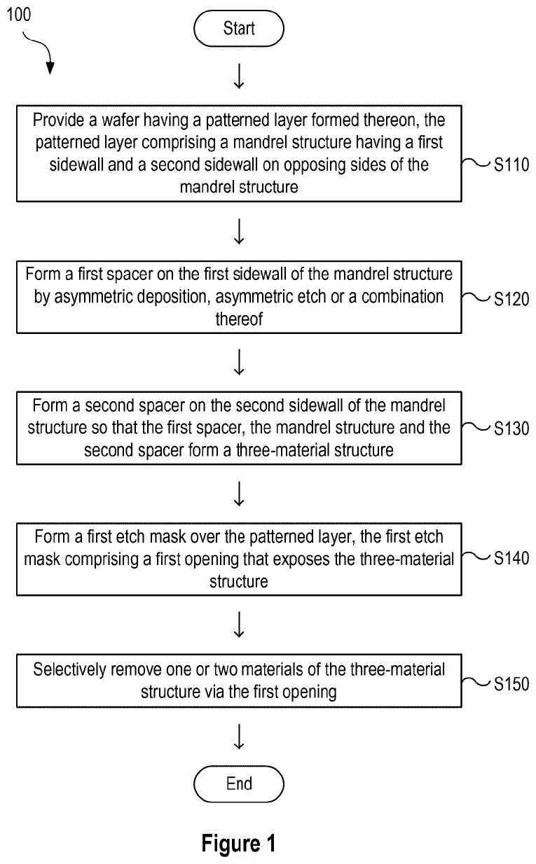

FIG. 1 shows a flow chart of a patterning process 100 in accordance with some embodiments of the present disclosure. At step S110, a wafer having a patterned layer formed thereon is provided. The patterned layer includes a mandrel structure having a first sidewall and a second sidewall on opposing sides of the mandrel structure. At step S120, a first spacer is formed on the first sidewall of the mandrel structure by asymmetric deposition, asymmetric etch or a combination thereof. At step S130, a second spacer is formed on the second sidewall of the mandrel structure so that the first spacer, the mandrel structure and the second spacer form a three-material structure. At step S140, a first etch mask is formed over the patterned layer. The first etch mask includes a first opening that exposes the three-material structure. At step S150, one or two materials of the three-material structure are selectively removed via the first opening.

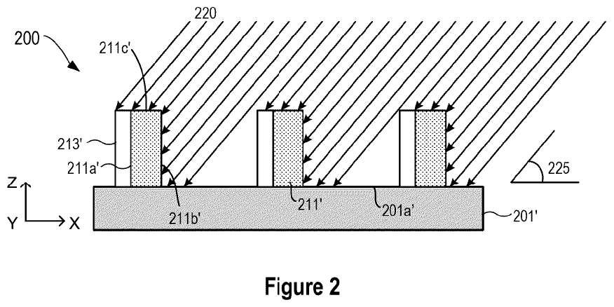

FIG. 2 shows a vertical cross-sectional view of a semiconductor device 200 in accordance with some embodiments of the present disclosure. As illustrated, the semiconductor device 200 includes a wafer (as shown by a top layer 201′ of the wafer) and a plurality of mandrel structures 211′ formed on the top layer 201′. The plurality of mandrel structures 211′ each include a first sidewall 211a′, a second sidewall 211b′ and a top surface 211c′. A spacer material 213′ can be formed at least on the first sidewall 211a′.

A directional plasma 220 represented by arrows can be used for asymmetrical etch purposes, for instance directional etch to remove undesirable portions of the spacer material 213′ from at least the second sidewall 211b′ and the top surface 211c′ while leaving the spacer material 213′ on the first sidewall 211a′. The directional plasma 220 can have an acute angle 225 relative to a top surface 201a′ of the top layer 201′. The acute angle 225 can be 30°-85°, e.g. 30°, 40°, 45°, 50°, 60°, 70°, 80°, 85°, or any values therebetween, depending on spacing and height of the plurality of mandrel structures 211′.

In some embodiments, the directional plasma 220 can be used for asymmetrical deposition purposes, for instance directional deposition of a material on the second sidewall 211b′ and the top surface 211c′ with no material deposition on the first sidewall 211a′. A directional etch that is substantially in the Z direction can then be executed to remove the material from the top surface 211c′ so that the material remains only on the second sidewall 211b′ to form a second spacer.

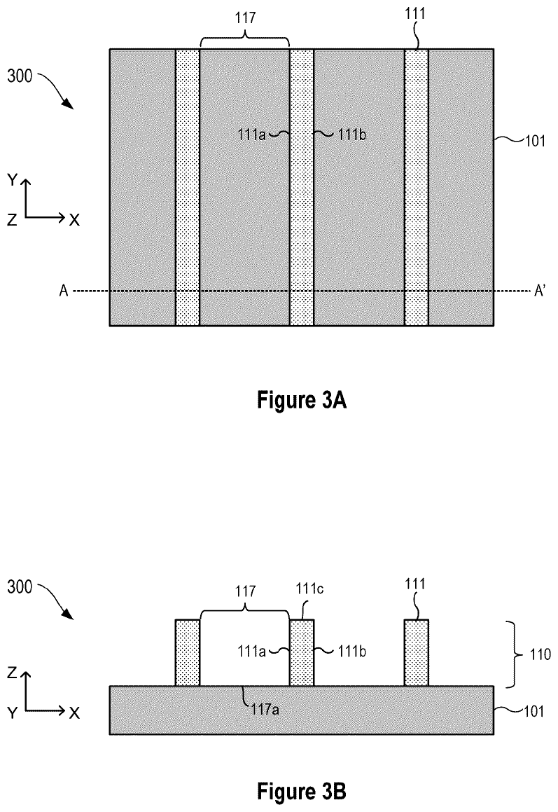

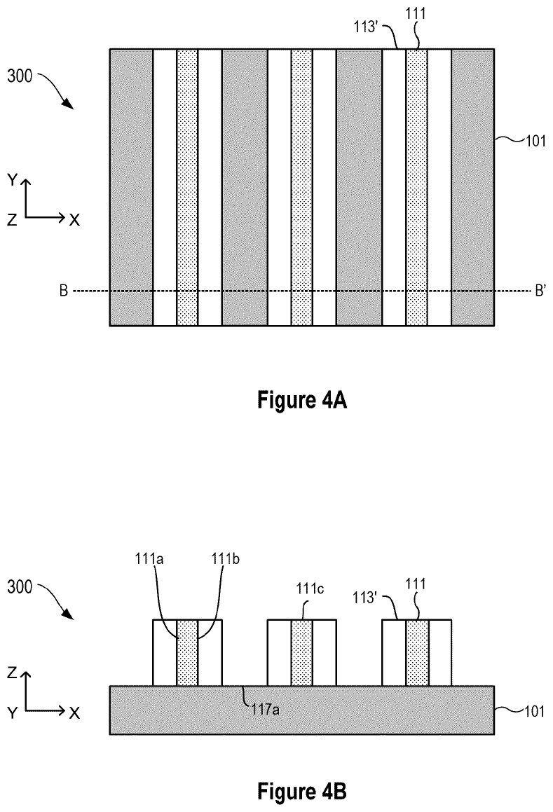

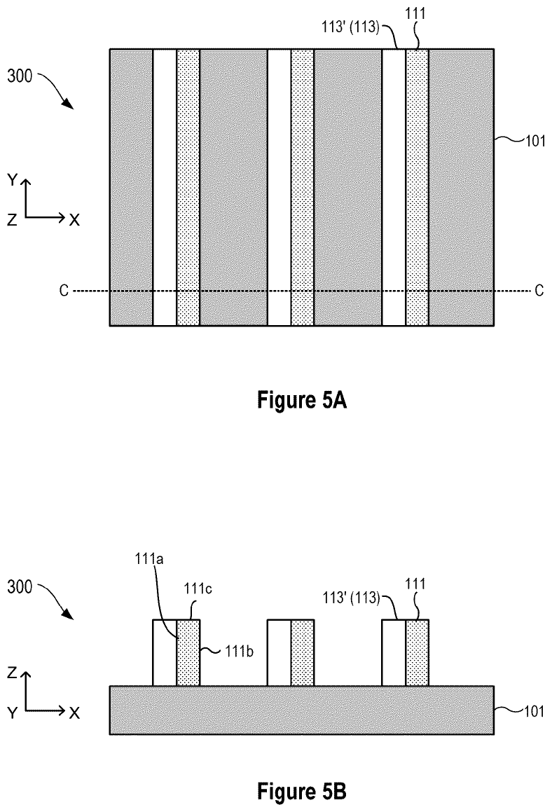

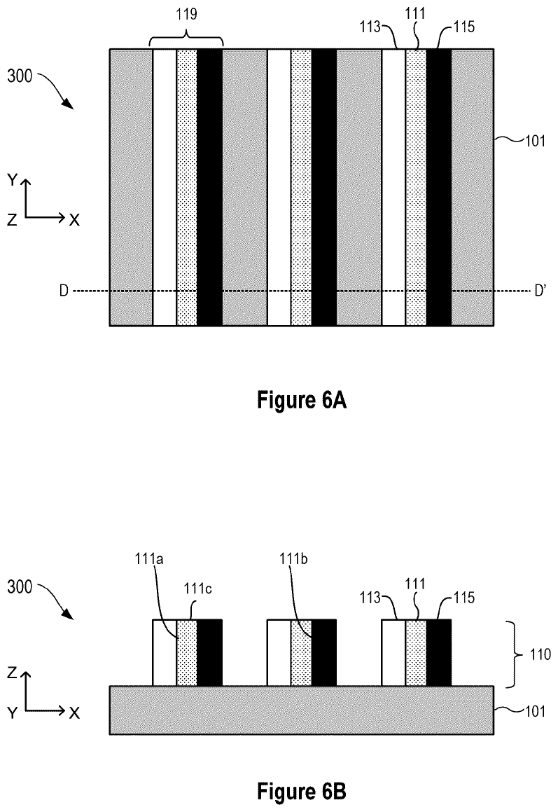

FIGS. 3A, 4A, 5A and 6A show examples of two-color spacer formation by asymmetric etch. Particularly, FIGS. 3A, 4A, 5A and 6A show top-down views of a semiconductor device 300 at various intermediate steps of patterning, and FIGS. 3B, 4B, 5B and 6B respectively show vertical cross-sectional views taken along the line cut AA′ in FIG. 3A, the line cut BB′ in FIG. 4A, the line cut CC′ in FIG. 5A and the line cut DD′ in FIG. 6A in accordance with some embodiments of the present disclosure.

As illustrated in FIGS. 3A and 3B, the semiconductor device 300 can include a wafer (as shown by a top layer 101 of the wafer) and a patterned layer 110 formed thereon. The patterned layer 110 can include at least one mandrel structure 111. The mandrel structure 111 includes a first sidewall 111a and a second sidewall 111b on opposing sides of the mandrel structure 111. The mandrel structure 111 also includes a top surface 111c. In some embodiments, the patterned layer 110 includes a plurality of mandrel structures (e.g. 111) that extend parallel to each other along the Y direction. A gap 117 exists between two neighboring mandrel structures. A bottom 117a of the gap 117 exposes the top layer 101 of the wafer.

In FIGS. 4A and 4B, a first spacer material 113′ can be formed, for example isotropically or conformally on the first sidewall 111a of the mandrel structure 111, on the second sidewall 111b of the mandrel structure 111, on the top surface 111c of the mandrel structure 111, and on the bottom 117a of the gap 117. Then a first directional etch process, for example substantially in the Z direction, can be executed to remove the first spacer material 113′ from horizontal surfaces including the top surface 111c of the mandrel structure 111 and the bottom 117a of the gap 117. The first directional etch process does not need to be chemically selective. As a result, the first spacer material 113′ remains on the first sidewall 111a and the second sidewall 111b of the mandrel structure 111.

In FIGS. 5A and 5B, the first spacer material 113′ can be removed from the second sidewall 111b by a second directional etch process that has an acute angle relative to the top layer 101 of the wafer or the bottom 117a of the gap 117, for example by side-selective etch techniques shown in FIG. 2. The second directional etch process is configured to selectively etch the first spacer material 113′, relative to the mandrel structure 111 and the top layer 101 of the wafer. Consequently, remaining portions of the first spacer material 113′ form a first spacer 113 on the first sidewall 111a while the second sidewall 111b is exposed. Accordingly, the second directional etch process is a side-selective etch process.

In FIGS. 6A and 6B, a second spacer 115 is formed on the second sidewall 111b. In one embodiment, a second spacer material can be deposited selectively on exposed portions of the mandrel structure 111, including the top surface 111c and the second sidewall 111b, for instance by selective deposition such as selective atomic layer deposition. Then, a third directional etch process, for example substantially in the Z direction, can be executed to remove the second spacer material from the top surface 111c. The third directional etch process is configured to selectively etch the second spacer material, relative to the mandrel structure 111, the top layer 101 of the wafer and the first spacer 113. As a result, remaining portions of the second spacer material form the second spacer 115 on the second sidewall 111b. Therefore, the first spacer 113, the mandrel structure 111 and the second spacer 115 form a three-material structure 119 that is also known as a two-color-spacer structure.

In another embodiment, the second spacer material can be deposited asymmetrically by techniques shown in FIG. 2. That is to say, the second spacer material can be deposited by the directional plasma 220 on the top surface 111c and the second sidewall 111b. Such asymmetrical deposition does not need to be chemically selective or include selective deposition. Then, the aforementioned third directional etch process can be executed to remove the second spacer material from the top surface 111c. Accordingly, such asymmetrical deposition is a side-selective deposition process.

In some embodiments, the first spacer 113, the mandrel structure 111, the second spacer 115 and the top layer 101 of the wafer include different materials from each other and thus can be configured to be etch-selective to each other. For example, the mandrel structure 111 can include, but is not limited to, silicon nitride, amorphous silicon, spin-on carbon, amorphous carbon, silicon oxide, silicon carbide, metal oxide, metal nitride, metal or a combination thereof. The first spacer 113 can include, but is not limited to, silicon nitride, amorphous silicon, silicon oxide, silicon carbide, metal oxide, metal nitride, metal or a combination thereof. The second spacer 115 can include, but is not limited to, silicon nitride, amorphous silicon, silicon oxide, silicon carbide, metal oxide, metal nitride, metal or a combination thereof. The top layer 101 of the wafer can include, but is not limited to, silicon nitride, amorphous silicon, silicon oxide, silicon carbide, metal oxide, metal nitride, metal, spin-on carbon, amorphous carbon, germanium, silicon germanium or a combination thereof.

In some preferred embodiments, the mandrel structure 111 can include silicon nitride, spin-on carbon, amorphous carbon, amorphous silicon, or a combination thereof. The first spacer 113 can include silicon oxide, silicon nitride, titanium oxide, titanium nitride, or a combination thereof. The second spacer 115 can include silicon oxide, silicon nitride, titanium oxide, titanium nitride, or a combination thereof. The top layer 101 of the wafer can include silicon, germanium, silicon germanium, or a combination thereof.

In one embodiment, the mandrel structure 111 includes silicon nitride. The first spacer 113 includes silicon oxide. The second spacer 115 includes titanium oxide, titanium nitride, or a combination thereof. The top layer 101 of the wafer includes silicon. In another embodiment, the mandrel structure 111 includes silicon nitride. The first spacer 113 includes titanium oxide, titanium nitride, or a combination thereof. The second spacer 115 includes silicon oxide. The top layer 101 of the wafer includes silicon.

In one embodiment, the mandrel structure 111 includes amorphous silicon. The first spacer 113 includes titanium oxide. The second spacer 115 includes silicon oxide. The top layer 101 of the wafer includes silicon. In another embodiment, the mandrel structure 111 includes amorphous silicon. The first spacer 113 includes silicon oxide. The second spacer 115 includes titanium oxide. The top layer 101 of the wafer includes silicon.

While 3A, 4A, 5A and 6A can show two-color spacer formation by asymmetric etch in some embodiments, FIGS. 3A, 5A and 6A can show two-color spacer formation by asymmetric deposition in other embodiments. For instance, going from FIG. 3A to FIG. 5A (without going through FIG. 4), the first spacer 113 can be formed on the first sidewall 111a by side-selective deposition techniques shown in FIG. 2. More specifically, the first spacer material 113′ can be formed on the first sidewall 111a and on the top surface 111c by a directional plasma (e.g. 220 and the like) that has an acute angle relative to the top layer 101 of the wafer or the bottom 117a of the gap 117. Subsequently, the first spacer material 113′ is removed from the top surface 111c by an anisotropic etch process so that remaining portions of the first spacer material 113′ forms the first spacer 113. The anisotropic etch process is configured to selectively etch the first spacer material 113′, relative to the mandrel structure 111 and the top layer 101 of the wafer. The anisotropic etch process can be accomplished by a plasma that is substantially in the Z direction. Then, the second spacer 115 can be formed on the second sidewall 111b as described earlier.

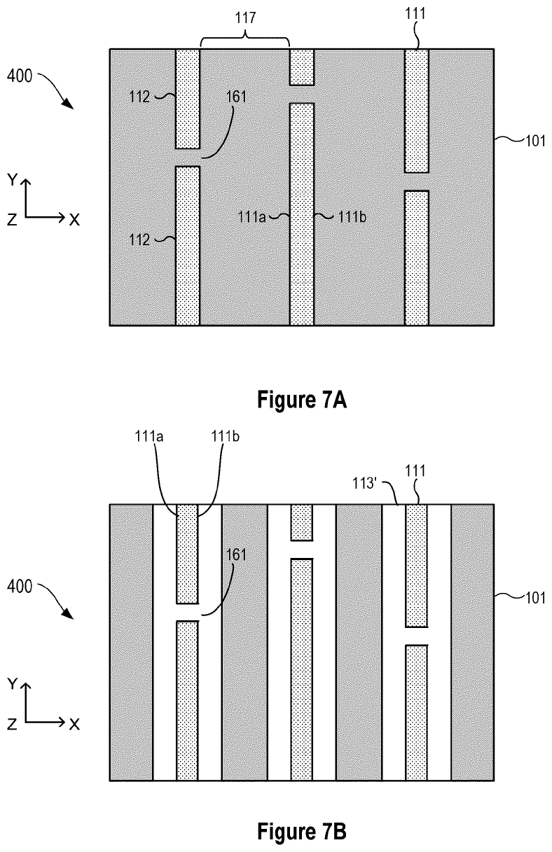

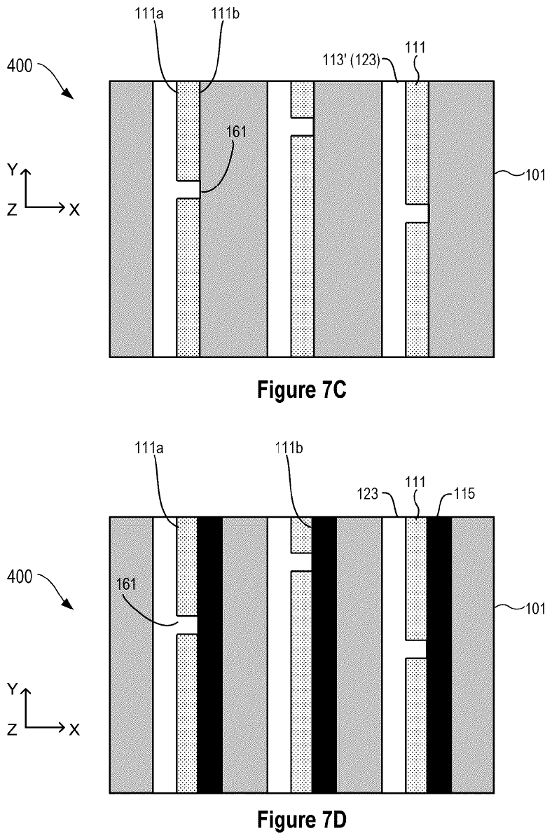

FIGS. 7A, 7B, 7C and 7D show top-down views of a semiconductor device 400 at various intermediate steps of patterning, in accordance with some embodiments of the present disclosure. The embodiment of the semiconductor device 400 in FIG. 7A is similar to the embodiment of the semiconductor device 300 in FIGS. 3A and 3B. Note that similar or identical components are labeled with similar or identical numerals unless specified otherwise. Descriptions have been provided above and will be omitted for simplicity purposes.

As shown in FIG. 7A, at least one cut structure (or a gap 161) can be formed in the mandrel structure 111 to divide the mandrel structure 111 into two sub-mandrel structures 112 that are spaced apart from each other by the gap 161.

In FIG. 7B, the first spacer material 113′ can be formed, for example isotropically on the first sidewall 111a, on the second sidewall 111b, on the top surface (e.g. 111c), on the bottom (e.g. 117a) of the gap 117 and in the gap 161. Then a first directional etch process, for example in the Z direction, can be executed to remove the first spacer material 113′ from horizontal surfaces including the top surface (e.g. 111c) of the mandrel structure 111 and the bottom (e.g. 117a) of the gap 117. The first directional etch process does not need to be chemically selective. As a result, the first spacer material 113′ remains on the first sidewall 111a and the second sidewall 111b as well as in the gap 161.

In FIG. 7C, a second directional etch process is executed that has an acute angle relative to the top layer 101 of the wafer for example by side-selective etch techniques shown in FIG. 2. As a result, remaining portions of the first spacer material 113′ forms a first spacer 123 that is on the first sidewall 111a of the mandrel structure 111 and fills the gap 161.

In FIG. 7D, the second spacer 115 can be formed on the second sidewall 111b of the mandrel structure 111, for example similar to FIGS. 6A and 6B.

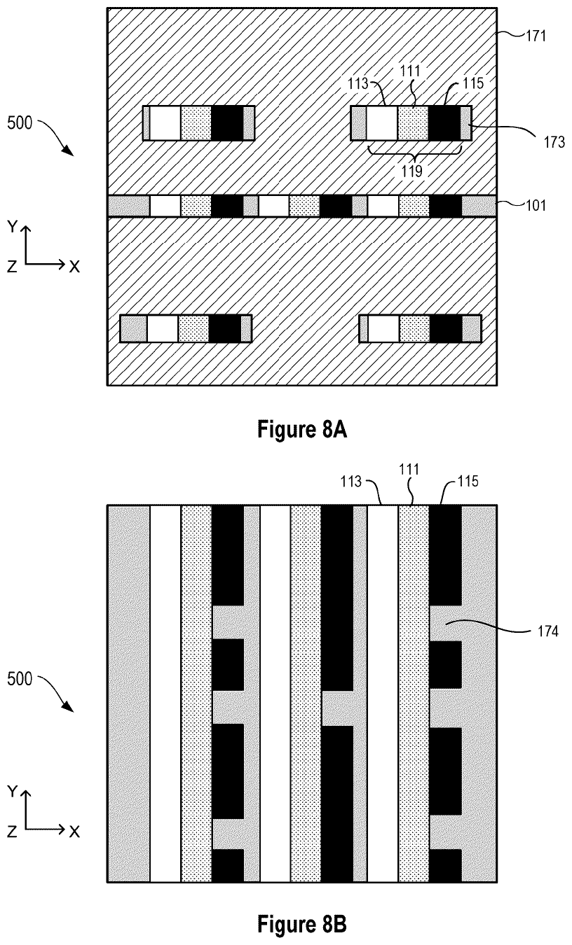

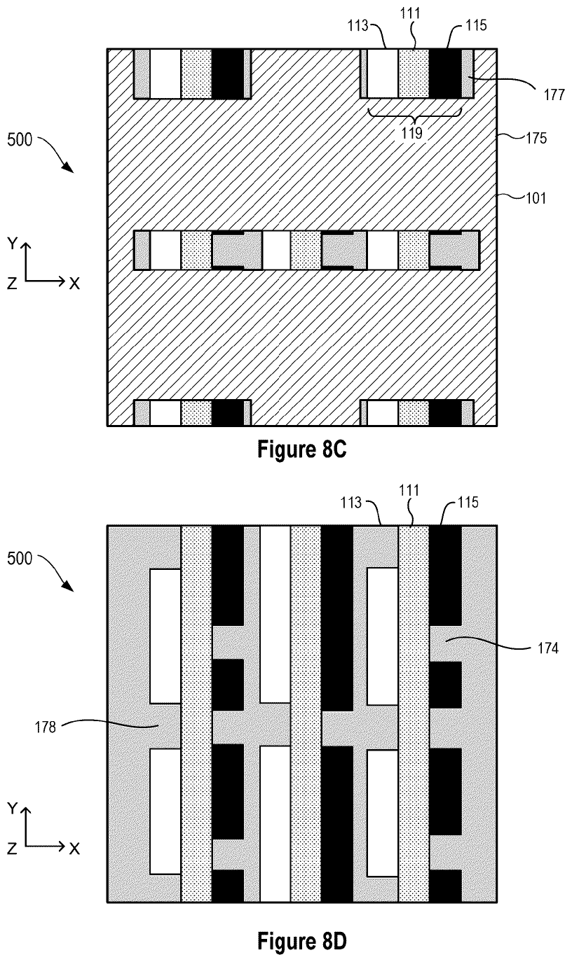

FIGS. 8A, 8B, 8C and 8D show top-down views of a semiconductor device 500 at various intermediate steps of patterning, in accordance with some embodiments of the present disclosure. Note that similar or identical components are labeled with similar or identical numerals unless specified otherwise. Descriptions have been provided above and will be omitted for simplicity purposes.

The semiconductor device 500 in FIG. 8A can be obtained by processing the semiconductor device 300 in FIGS. 6A and 6B, for example by forming a first etch mask 171 over the patterned layer 110 by lithography exposure and etch. The first etch mask 171 includes a first opening 173 that exposes the three-material structure 119.

In some embodiments, the first opening 173 of the first etch mask 171 is not aligned with the three-material structure 119 in that at least one boundary of the first etch mask 171 is outside the three-material structure 119. As a result, the first opening 173 also exposes the top layer 101 of the wafer. As discussed above, the first spacer 113, the mandrel structure 111, the second spacer 115 and the top layer 101 of the wafer can include different materials and be configured to be etch-selective to each other.

Accordingly, despite the misalignment between the first opening 173 and the three-material structure 119, selective etch can be performed to avoid edge placement errors as shown in FIG. 8B. Part of the second spacer 115 is selectively removed via the first opening 173 to create a gap 174 in the second spacer 115 while other materials (e.g. the first spacer 113, the mandrel structure 111 and the top layer 101 of the wafer) are not appreciably affected. The first etch mask 171 is then etched away. Therefore, cut patterning can be accomplished using larger cut sizes without as much risk for lithography overlay issues. In other words, the first opening 173 can be larger than and misaligned with the underlying feature (i.e. the three-material structure 119 in this case) without introducing edge placement errors due to etch selectivity.

While the first opening 173 is not aligned with the three-material structure 119 in the example of FIG. 8A, it should be understood that the first opening 173 may be aligned with the three-material structure 119 in other examples, and similar or identical etch results as shown in FIG. 8B can be achieved by selective etch.

In FIG. 8C, a second etch mask 175 is formed over the patterned layer 110. The second etch mask 175 includes a second opening 177 that exposes the three-material structure 119. Similarly, the second opening 177 may or may not be aligned with the three-material structure 119. For illustrative purposes, the second opening 177 in this example is not aligned with the three-material structure 119 and thus exposes the first spacer 113, the mandrel structure 111, the second spacer 115 and the top layer 101 of the wafer.

In FIG. 8D, despite the misalignment between the second opening 177 and the three-material structure 119, selective etch can be performed to avoid edge placement errors. Part of the first spacer 113 is selectively removed via the second opening 177 to create a gap 178 in the first spacer 113 while other materials (e.g. the mandrel structure 111, the second spacer 115 and the top layer 101 of the wafer) are not appreciably affected. The second etch mask 175 is then etched away.

In the examples of FIGS. 8A-8D, the second spacer 115 is selectively removed before the first spacer 113 is selectively removed. In other examples, the second spacer 115 can be selectively removed after the first spacer 113 is selectively removed. For instance, the second etch mask 175 can be formed over the patterned layer 110 in FIGS. 6A and 6B. Then, part of the first spacer 113 is selectively removed via the second opening 177 to create the gap 178. Subsequently, the second etch mask 175 is removed, and the first etch mask 171 is formed over the patterned layer 110. Next, part of the second spacer 115 is selectively removed via the first opening 173 to create the gap 174 before the first etch mask 171 is removed.

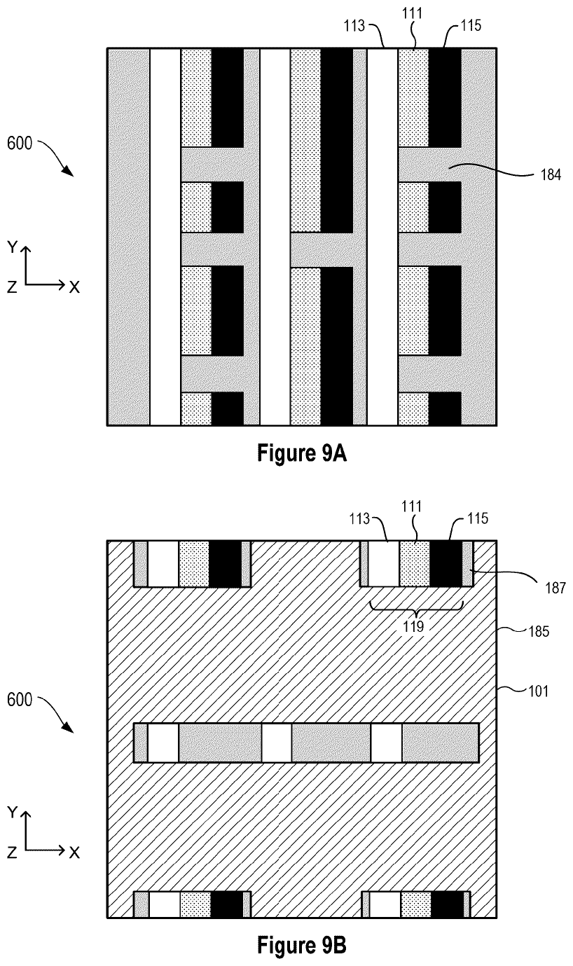

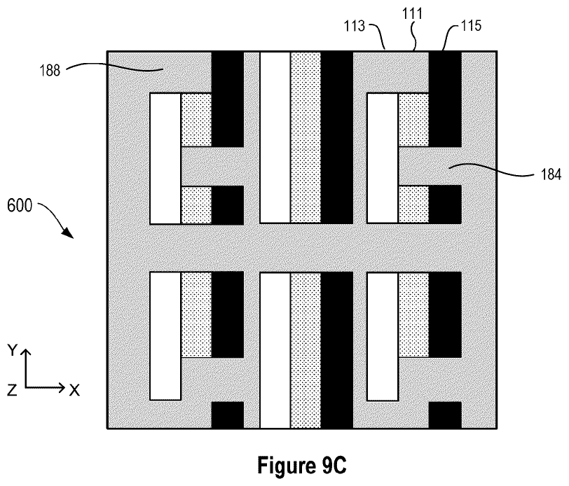

FIGS. 9A, 9B and 9C show top-down views of a semiconductor device 600 at various intermediate steps of patterning, in accordance with some embodiments of the present disclosure. Note that similar or identical components are labeled with similar or identical numerals unless specified otherwise. Descriptions have been provided above and will be omitted for simplicity purposes.

The semiconductor device 600 in FIG. 9A can be obtained by processing the semiconductor device 500 in FIG. 8A, for example by selectively etching the second spacer 115 and the mandrel structure 111 relative to the first spacer 113 and the top layer 101 of the wafer. As a result, a gap 184 is created in the second spacer 115 and the mandrel structure 111. The first etch mask 171 is then etched away.

In FIG. 9B, a third etch mask 185 is formed over the patterned layer 110. The third etch mask 185 includes a third opening 187 that exposes the three-material structure 119. Similarly, the third opening 187 may or may not be aligned with the three-material structure 119. For illustrative purposes, the third opening 187 in this example is not aligned with the three-material structure 119 and thus exposes the first spacer 113, the mandrel structure 111, the second spacer 115 and the top layer 101 of the wafer.

In FIG. 9C, despite the misalignment between the third opening 187 and the three-material structure 119, selective etch can be performed to avoid edge placement errors. Part of the first spacer 113 and part of the mandrel structure 111 are selectively removed via the third opening 187 to create a gap 188 in the first spacer 113 (and the mandrel structure 111) while other materials (e.g. the second spacer 115 and the top layer 101 of the wafer) are not appreciably affected. The third etch mask 185 is then etched away. The gap 188 and the gap 184 may be spaced apart from each other. The gap 188 and the gap 184 may alternatively be connected to each other.

In the examples of FIGS. 9A-9C, the second spacer 115 and the mandrel structure 111 are selectively removed before the first spacer 113 and the mandrel structure 111 are selectively removed. In other examples, the second spacer 115 and the mandrel structure 111 can be selectively removed after the first spacer 113 and the mandrel structure 111 are selectively removed. For instance, the third etch mask 185 can be formed over the patterned layer 110 in FIGS. 6A and 6B. Then, part of the first spacer 113 and part of the mandrel structure 111 are selectively removed via the third opening 187 to create the gap 188. Subsequently, the third etch mask 185 is removed, and the first etch mask 171 is formed over the patterned layer 110. Next, part of the second spacer 115 and part of the mandrel structure 111 are selectively removed via the first opening 173 to create the gap 184 before the first etch mask 171 is removed.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” and “wafer” as used herein are interchangeable and generically refer to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of microfabrication, the method comprising:
providing a wafer having a patterned layer formed thereon, the patterned layer comprising a mandrel structure having a first sidewall and a second sidewall on opposing sides of the mandrel structure;
forming a first spacer on the first sidewall of the mandrel structure by asymmetric deposition, asymmetric etch or a combination thereof;
forming a second spacer on the second sidewall of the mandrel structure so that the first spacer, the mandrel structure and the second spacer form a three-material structure;
forming a first etch mask over the patterned layer, the first etch mask comprising a first opening that exposes the three-material structure; and
selectively removing one or two materials of the three-material structure via the first opening.

2. The method of claim 1, wherein:
the first opening of the first etch mask is not aligned with the three-material structure in that at least one boundary of the first etch mask is outside the three-material structure.

3. The method of claim 2, wherein:
the wafer comprises a top layer that is in direct contact with the patterned layer, and
the first opening of the first etch mask also exposes the top layer of the wafer.

4. The method of claim 3, wherein:
the first opening exposes four different materials consisting of the first spacer, the mandrel structure, the second spacer and the top layer.

5. The method of claim 1, wherein the selectively removing comprises:
selectively etching the first spacer, or both the first spacer and the mandrel structure, in the first opening.

6. The method of claim 5, further comprising:
removing the first etch mask;
forming a second etch mask over the patterned layer, the second etch mask comprising a second opening that exposes the three-material structure; and
selectively etching the second spacer, or both the second spacer and the mandrel structure, in the second opening.

7. The method of claim 1, wherein the selectively removing comprises:
selectively etching the second spacer, or both the second spacer and the mandrel structure, in the first opening.

8. The method of claim 7, further comprising:
removing the first etch mask;
forming a second etch mask over the patterned layer, the second etch mask comprising a second opening that exposes the three-material structure; and
selectively etching the first spacer, or both the first spacer and the mandrel structure, in the second opening.

9. The method of claim 1, further comprising:
forming a gap in the mandrel structure to divide the mandrel structure into two sub-mandrel structures that are spaced apart from each other by the gap; and
filling the gap with the first spacer.

10. The method of claim 9, further comprising:
forming a first spacer material isotropically around the mandrel structure, including in the gap; and
executing a directional etch process that has an acute angle relative to a working surface of the wafer so that remaining portions of the first spacer material forms the first spacer that is on the first sidewall of the mandrel structure and fills the gap.

11. The method of claim 1, wherein the first spacer is formed on the first sidewall of the mandrel structure at least by the asymmetric deposition that comprises:
forming a first spacer material on the first sidewall of the mandrel structure and on a top surface of the mandrel structure by a directional plasma that has an acute angle relative to a working surface of the wafer; and
removing the first spacer material from the top surface of the mandrel structure by an anisotropic etch process so that remaining portions of the first spacer material forms the first spacer.

12. The method of claim 11, wherein:
the acute angle is 30°-85°.

13. The method of claim 1, wherein the first spacer is formed on the first sidewall of the mandrel structure at least by the asymmetric etch that comprises:
forming a first spacer material on the first sidewall of the mandrel structure and on the second sidewall of the mandrel structure; and
removing the first spacer material from the second sidewall of the mandrel structure by a directional etch process that has an acute angle relative to a working surface of the wafer.

14. The method of claim 13, further comprising:
executing an anisotropic etch process that is substantially perpendicular to the working surface of the wafer to etch the first spacer material.

15. The method of claim 1, wherein:
the first spacer, the mandrel structure and the second spacer are configured to be etch-selective to each other.

16. The method of claim 15, wherein:
the mandrel structure comprises silicon nitride, spin-on carbon, amorphous carbon, amorphous silicon, or a combination thereof,
the first spacer comprises silicon oxide, silicon nitride, titanium oxide, titanium nitride, or a combination thereof, and
the second spacer comprises silicon oxide, silicon nitride, titanium oxide, titanium nitride, or a combination thereof.

17. The method of claim 16, wherein:
the mandrel structure comprises silicon nitride,
one of the first spacer and the second spacer comprises silicon oxide, and
the other one of the first spacer and the second spacer comprises titanium oxide, titanium nitride, or a combination thereof.

18. The method of claim 16, wherein:
the mandrel structure comprises amorphous silicon,
one of the first spacer and the second spacer comprises titanium oxide, and
the other one of the first spacer and the second spacer comprises silicon oxide.

19. The method of claim 16, wherein:
the wafer comprises a top layer that is in direct contact with the patterned layer, and
the top layer comprises silicon, germanium, silicon germanium, or a combination thereof.

20. The method of claim 1, wherein:
the patterned layer comprises a plurality of mandrel structures that extend substantially parallel to one another.
